(19) United States
(12) Patent Application Publication
(10) Pub. No.: US 2025/0079187 A1
(43) Pub. Date: Mar. 6, 2025

(54) HIGH THERMAL CONDUCTIVITY SUBSTRATE

(71) Applicant: Phononics Ltd, Nesher (IL)

(72) Inventors: Shaul Michaelson, Nesher (IL); Joseph Kaplun, Petach-Tikwa (IL); Anna Kosinova, Nesher (IL); Inbar Dag, Nesher (IL); Shye Shapira, Kiryat Tivon (IL)

(73) Assignee: Phononics Ltd, Nesher (IL)

(21) Appl. No.: 18/509,292

(22) Filed: Nov. 14, 2023

Related U.S. Application Data
(60) Provisional application No. 63/579,912, filed on Aug. 31, 2023.

(51) Int. Cl. H01L 21/48; H01L 23/373

(52) U.S. Cl. CPC H01L 21/4803; H01L 23/3732

(57) ABSTRACT

There is provided a method for manufacturing a diamond cooled device, the method includes (a) obtaining a semiconductor item that includes active elements that emit heat during operation; (b) obtaining via location information regarding vias associated with the active elements; (c) obtaining a diamond layer that comprises openings that are located at positions determined based on the via location information; and (d) bonding the diamond layer to the semiconductor item to provide a bonded item, following the obtaining of the diamond layer.

### BACKGROUND

Thermal management in semiconductor devices and circuits is a critical design element in any manufacturable and cost-effective electronic and optoelectronic product, such as light generation and electrical signal amplification. The goal of efficient thermal design is to lower the operating temperature of such electronic or optoelectronic device while maximizing performance (power and speed), efficiency and reliability.

Examples of such devices are high speed digital integrated circuits, microwave transistors, light emitting diodes and lasers. Depending on the frequency of operation, power requirements, and specific application, these devices have been conventionally made on silicon, gallium arsenide (GaAs), or indium phosphide (InP).

In recent years, gallium nitride (GaN), aluminum nitride (AlN) and other wide-gap semiconductors have surfaced as new choices for both power electronics and visible-light generating optoelectronics. Gallium nitride material system supports microwave transistors with high-electron mobility (necessary for high-speed operation), high breakdown voltage (necessary for high power), and thermal conductivity that is greater than GaAs, InP, or silicon, and thus suitable for use in high power applications.

In spite of the high-temperature performance (owing to its wide band gap and high critical field), GaN electronic and optoelectronic devices are limited in performance due to relatively low thermal conductivity of the substrates commonly used for growth of GaN. GaN is just an example of semiconductor technology, other semiconductor materials can be used.

The limitation of the device performance due to overheating is well known also in the silicon device platforms, although at lower temperature range.

A solution based on diamond heat spreaders, located selectively at the hot areas identified by automatic design tools was presented in US patent application US2023/0214570A1. This solution involves positioning of the diamond HS (Heat Spreaders) at the back side of the semiconductor substrate. However, in some cases there is a need for electrical contacts through the back side of the substrate, which may connect the chip to a substrate, electronic board or package, or to lower level chip. For such cases, there is a need for creation of through diamond via (TDV) holes and electrical contacts.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 illustrates an example of an integration model, where ex-situ diamond is bonded to blanket device layer and serves as a hard mask for final via creation;

FIG. 2 illustrates an example of an integration model, where ex-situ diamond is bonded to ex-situ device layer;

FIG. 3 illustrates an example of an integration model, where blanket diamond is bonded to blanket device layer, wherein vias are created by patterning and etching of both layers;

FIG. 4 illustrates an example of an integration model, where the diamond functions as an interposer;

FIG. 5 illustrates an example of a method of thermochemical via creation;

FIG. 6 illustrates an example of a method of the PR pattering and subsequent RIE via creation;

FIG. 7 illustrates a pillared substrate on which the diamond layer is grown;

FIG. 8 illustrates an integration model in which the via openings are filled with electric conductive material to provide vias; and

FIG. 9 illustrates an example of an integration model in which the via openings of the diamond are filled before bonding and via openings of the device wafer are formed before bonding.

### DETAILED DESCRIPTION OF THE DRAWINGS

Any reference to a system should be applied, mutatis mutandis to a method that is executed by the system.

Any reference to method should be applied, mutatis mutandis to system that is configured to execute the method and/or to a device manufactured by the method.

There is provided a diamond layer that has openings. The openings are formed before bonding the diamond layer to other elements. The openings may be empty or filled before the bonding.

There are provided complete integration schemes, including the design of a thermal solution based on diamond HS, with electrical contacts based on TDVs which are integrated with the semiconductor device in by a few alternatives of process integration sequences presented herein.

According to an embodiment, there is provided a manufacturing method for manufacturing a synthetic diamond (either single crystal or poly crystalline) device that includes a diamond film and may also include corresponding holes in a wafer device, and there may be provided a diamond device.

According to an embodiment, the MCD device is included in high-power electronic devices, optoelectronic devices, gallium nitride-based electronic devices, high-electron mobility transistors, radio-frequency (RF) electronic devices, light emitting-diodes, lasers, and the like.

According to an embodiment, the method includes an integration of a MCD film and semiconductor device wafer. For simplicity we use the terminology “wafer”, but both bonded sides the semiconductor and the diamond can be a wafer, a segment of a wafer, a die, a segment of a die. Similarly, we demonstrate the method for wafer to wafer bonding but it can be die to die bonding, diamond die to semiconductor wafer, or semiconductor die to diamond wafer.

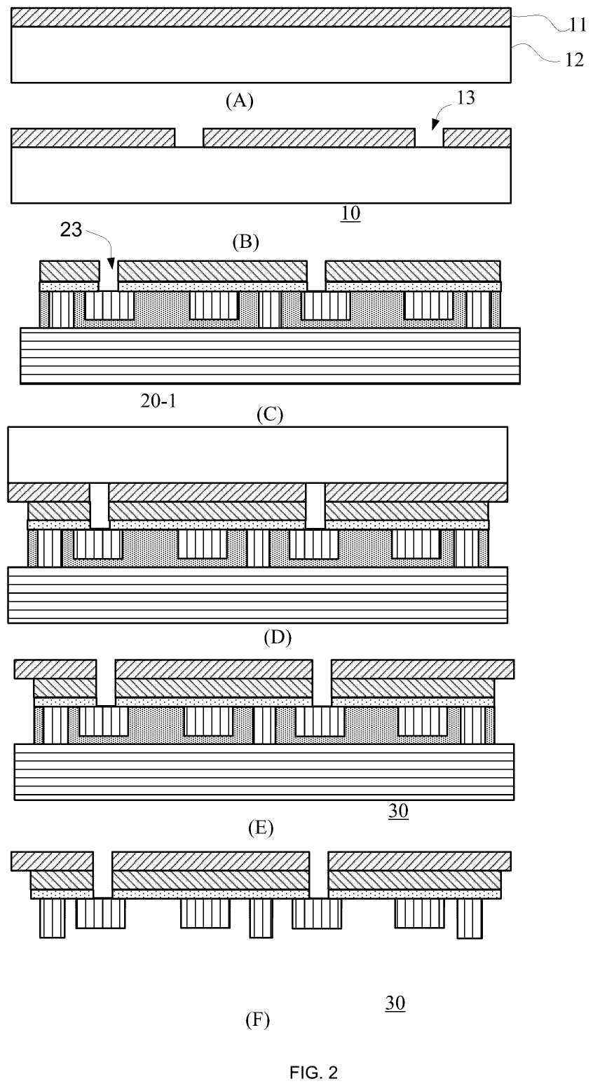

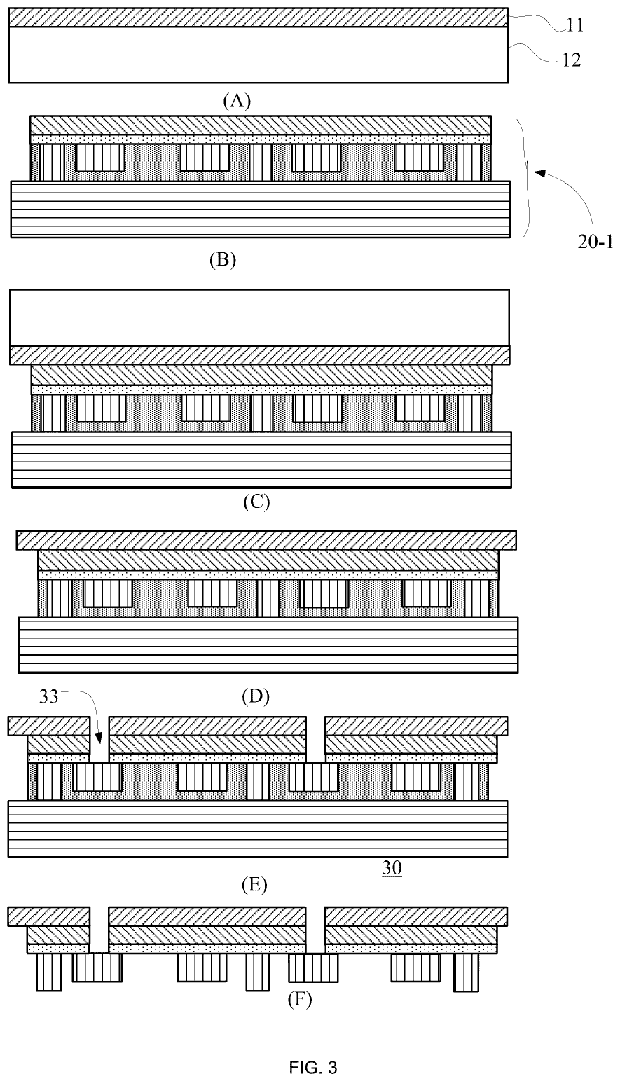

According to an embodiment, the method forms holes (such as via holes) in a MCD layer to provide the MCD layer, prior to the attachment of the MCD layer to a device wafer (FIG. 2 and FIG. 3). In such a case the polished MCD layer may be chemically bonded to a device wafer and via holes may be formed (in part after the bonding) and may play a role of the metallization channels. This method may be used to enable area-efficient grounding of the wafer devices and the use of microstrip transmission-lines.

One of the challenges in via hole fabrication is to etch 50-100 μm of substrate material at a fast rate and still be able to stop once the substrate is removed from the milling device and the thin metal contact (typically 0.1 to 2 μm) is exposed. In addition, low thermal budget requirements prevent rising etching temperature above 250-300° C. At these conditions, etch rate is typically <<1 μm/min.

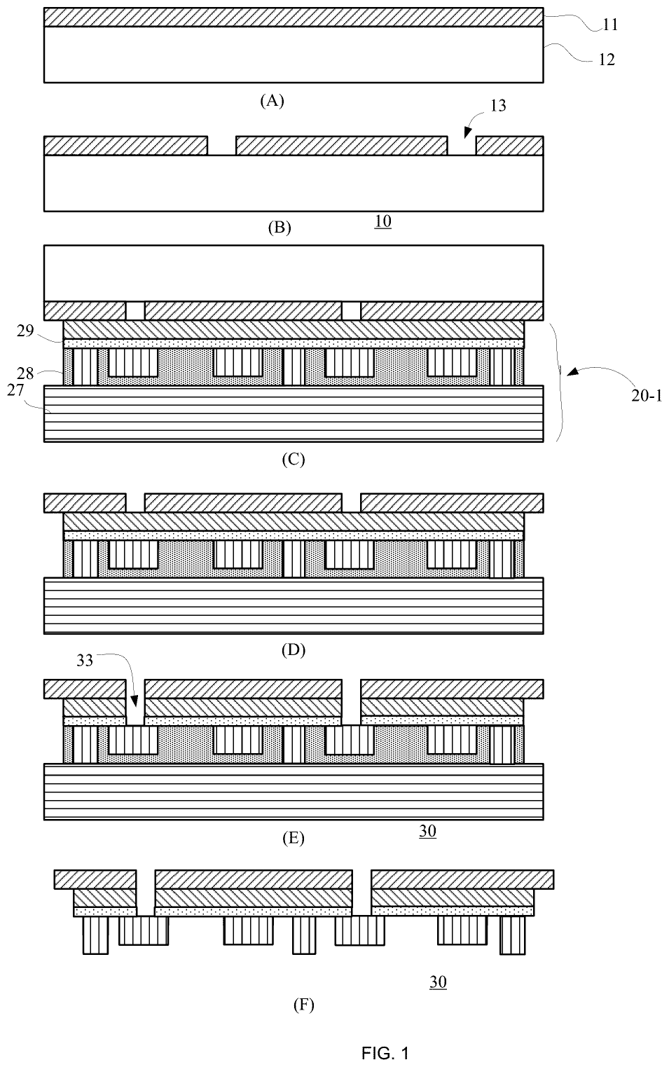

The methods described in FIG. 1 and FIG. 2 separate between the via hole creation in a MCD layer and the bonding of the MCD layer to a device wafer.

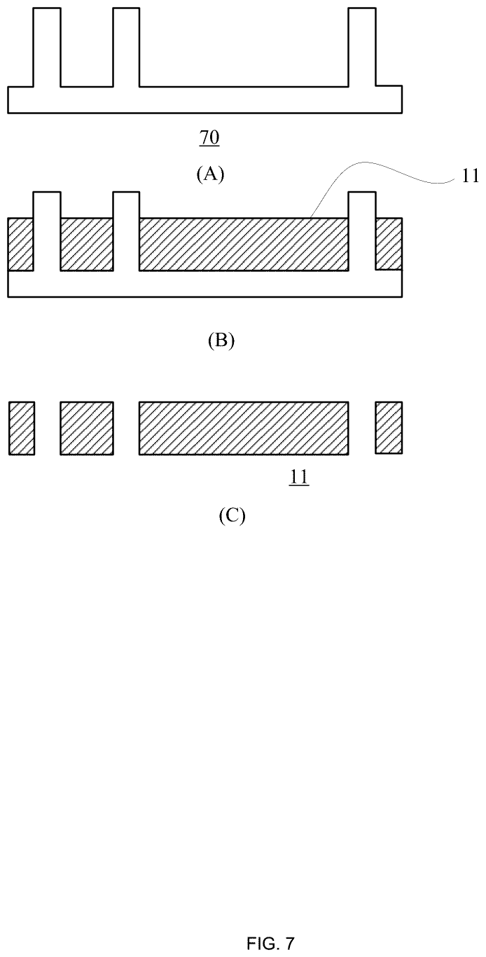

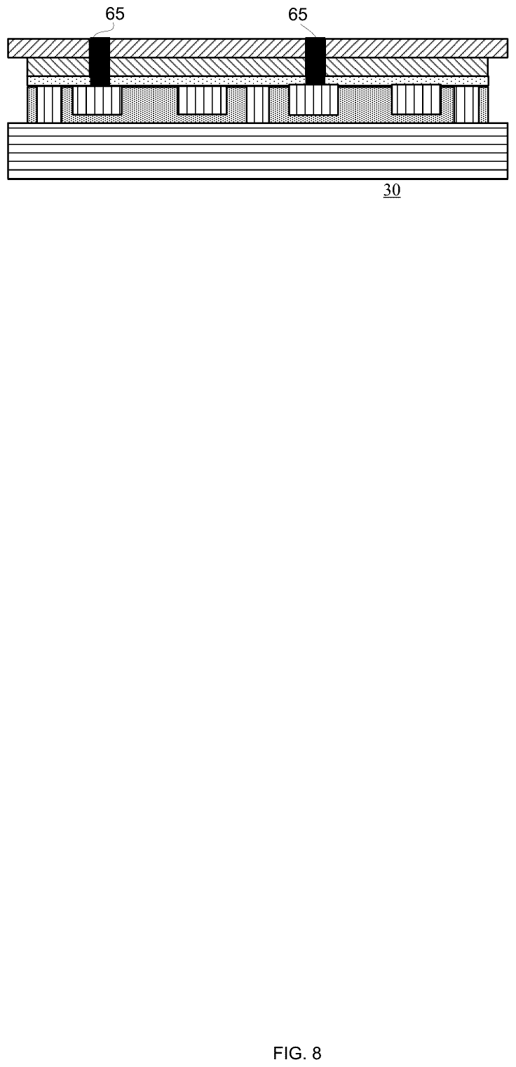

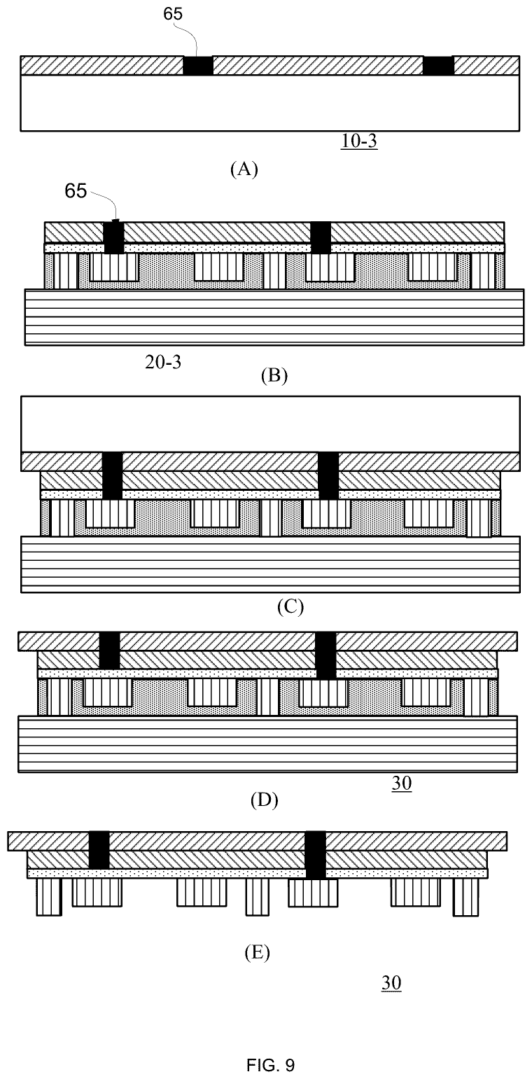

An example of the method is shown in FIG. 1 and FIG. 2, and includes:
a. Growing a MCD film 11 on a substrate 12 (for example Si or other material) to provide an initial MCD stack. This step is denoted (A) in FIG. 1. The growth substrate may be removed after diamond growth is finished or at a later stage. FIG. 7 illustrates (a) an example of a pillared substrate 70, (b) openings (in-situ via) formation during CVD diamond growth 11 on the pillared substrate, and (c) a diamond layer after separation from the pillared substrate.
b. Creating holes such as via holes (also referred to as via openings) in the MCD film to provide an initial MCD stack with a MCD film. This may be followed by polishing the MCD film before or after the via holes creation. This step is denoted (B) in FIG. 1. The outcome of step (B) is denoted 10.
c. Temporary bonding of a device wafer to a carrier using a temporary bonding polymer followed by thinning of a device wafer to a required thickness.
d. Via opening creation (this step is optional) in the semiconductor device layer. Via openings creation in the semiconductor device layer before bonding are shown in step (C) of FIG. 2. Via creation by filling the via openings before bonding are illustrated in FIG. 9. Via creation by filling the via openings after bonding is illustrated in FIGS. 1-3.
e. Bonding a device wafer to the initial MCD stack with the MCD film. One of the device wafer and the initial MCD stack with the MCD film may be turned upside down to that the MCD film faces the backside (for example one or more residual layers) of the device wafer before bonding—and is bonded to the backside of the device wafer. This step is denoted (C) in FIG. 1.
f. Removing the temporary substrate if it was not removed at an earlier stage. This step is denoted (D) in FIG. 1.
g. Etching (optional step) of the backside of the device wafer (for example one or more residual layers) to form via holes that are formed by the holes of the MCD layer and holes in the backside layer (for example one or more residual layers) of the device wafer. The holes in the backside layer (for example one or more residual layers) are formed during step (E). The etching may use the MCD layer as a etch mask, or alternatively, hard mask can be added on top of the MCD layer.
h. Filling the vias by any state-of-the-art metallization method including all the required steps for cleaning and surface preparation. See, for example FIG. 8. Vias are denoted 65.
i. Removing the temporary carrier 27 and temporary bonding layer 28 to provide a diamond cooled semiconductor device. This can be done also at the earlier stage. This step is denoted (F) in FIG. 1.

Step (b) of forming the holes in the MCD layer may be performed using any method. For example—it may include one of laser drilling, etching through thermochemical reaction, dry etch and heat in air. The benefit of creating a wafer prior to bonding to the semiconductor device wafer is clear: the diamond can tolerate aggressive process conditions, without any harm, and the cleaning process of bye-products created during via hole formation is much easier for free standing diamond wafer.

Laser drilling is a convenient method to form through-wafer via holes. This technique has been shown to be capable of very high etch rates and precise control of the via size and sidewall slope. Laser drilling is often used to machine hard materials such as superalloys. A simple model suggests that, above a threshold laser power density, the surface of the MCD material is melted and subsequently burned in oxidizing environment. A further advantage of the laser drilling technique is that the via hole pattern and the size of the vias can be readily controlled by computer-controlled x-y positioning of the MCD substrate, allowing much more flexibility and reducing costs relative to the need for producing a separate mask in plasma etch processes.

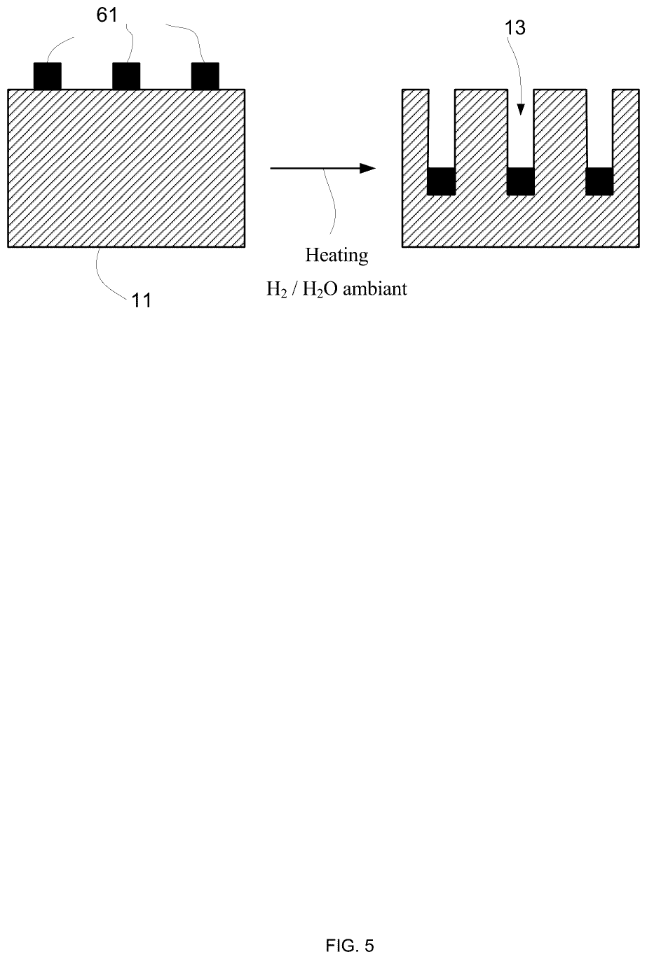

Etching through thermochemical reaction—in the mechanical machining field, it is well known that diamond tools wear severely when used for workpieces containing transition metals such as Fe, Ni, Co and Ti because of thermochemical reaction between the diamond and the metals. This reaction has been employed for etching and patterning diamond. For example, anisotropic diamond etching can be done by means of thermochemical reaction with Fe, Ni, Co or Ti in high temperature hydrogen, methane or water vapor. This process is shown schematically in FIG. 5—in which metal elements 61 are used to form via holes 13 in the MCD layer 11. In this case carbon atoms on the diamond surface contacting the metal film dissolve in the metal as a result of a solid solution reaction, then the dissolved C atoms diffuse upwards in accordance with the concentration gradient in the metal film. Finally, the C atoms arriving at the metal surface absorb from the sample as CO₂ and CH₄ gases. Thereby, the solid solution reaction is promoted, leading to high rate of diamond etching (up to 10 μm/min). In addition, using thermochemical reaction approach high throughput batch tools can be used (compared to single wafer process in the case of dry etching).

Heat in air-similar process sequence as in dry etching can be applied on the wafers heated in air. This is a simpler process allowing use the batch systems at higher throughput without involving expensive plasma equipment. A similar step sequence as shown in FIG. 5 will be applied, while the wafer will enter air or other oxidizing ambient (e.g. O₃ or H₂O) at elevated temperatures that will result in diamond burning and via holes creation.

Via formation in the diamond may be done in-situ during the growth process, if a pillared substrate is used, i.e. a substrate which is pre-designed to have pillars at the shape, size and distribution required for the device. The pillared substrate may be a sacrificial substrate which is etched away to leave the empty holes. For example, it can be made of silicon which later is etched away by wet etching method. Alternatively, it can be done as a temporary substrate with relatively weak adhesion and can be separated from the as grown diamond after growth. For example, via formation in the diamond can be done by molybdenum that can be recycled for the next growth. A third option is a substrate where the metal and the vias stay an integral part of the substrate.

The design of the pillars may be done as part of the device design by state of the art CAD design tools, with optimization both for the HS size and shape for optimal heat spreading, and the via size and location for electrical contacts.

The shape of the pillars may be vertical, conical, trapezoidal or any required shape that will allow easy separation of the diamond layer from the substrate, easy metallization process, and will meet the design rules of the device.

The height of the pillars may be identical to the thickness of the diamond layer, shorter, or taller. In case shorter pillars are used, the TDV holes will be opened during the post growth polishing step.

This method of in-situ via formation has a great economic benefit since it avoids expensive steps of via formation. Since the price of diamond HS currently allows the use only for high end applications, such a significant step towards more economical worthy process may be the differentiator for use in mass production for large variety of applications.

The methods described so far can be categorized as “via before bonding” path, which have the benefit of using process conditions that do not have to be adjusted to the survival of semiconductor devices. This approach requires alignment of the TDV in the diamond wafer to the device structure, but since methods for back side alignment are widely used, this is not a limiting factor.

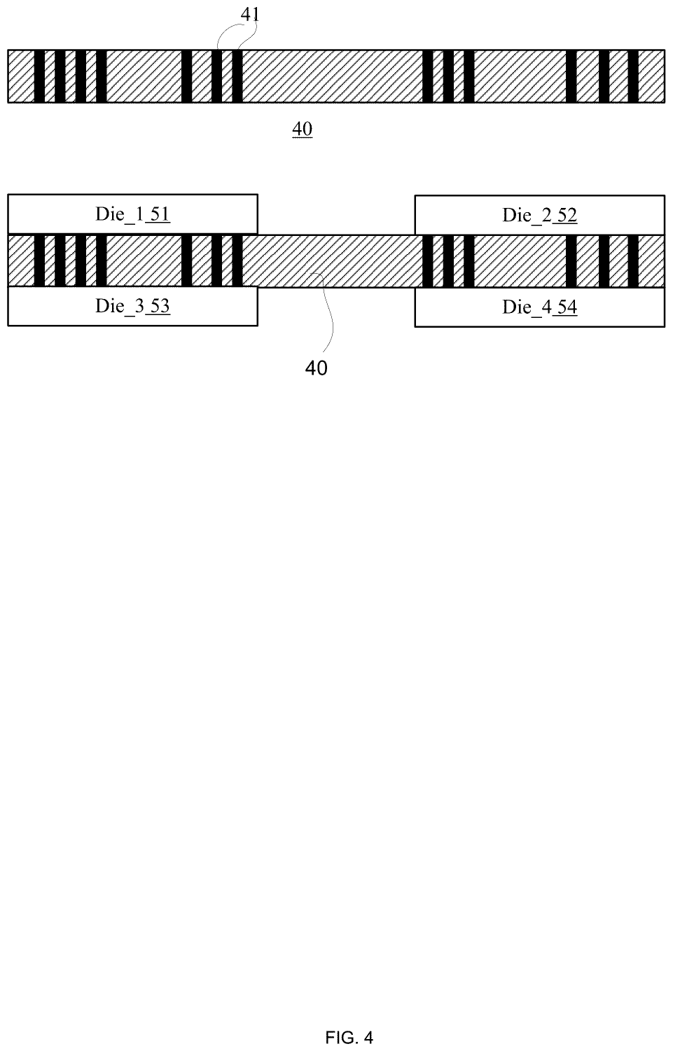

The established methods of preparing a diamond wafer with TDVs opens a new field for the application of diamond as an interposer, as illustrated in FIG. 4. Currently, interposers used in packaging are usually made of silicon, allowing transmission of signals between die to die, or die to package. Silicon interposers allow a limited frequency range due to the substrates' electrical conductivity, they also have a limited thermal conductivity and hence are poor heat spreaders. Diamonds have excellent heat conductivity and no electrical conductance and therefore may function both as heat spreader and as an interposer for transmission of electrical signals.

Another approach can be categorized as “bonding before via”, that have the benefit that there is no need for alignment between the TDV and the device, and there is no need to solve the challenge of bonding a perforated wafer. With this approach, the process conditions should be selected in a way they will not harm the semiconductor device.

The method may form holes (such as via holes) in a MCD layer following the attachment of the blanket MCD layer to a blanket device wafer (step (E) of FIG. 3). In such a case via hole creation can be done by means of dry etch. Dry etch-high temperature gas phase etching processes can be used to etch diamond, device layer or both (FIG. 5). In typical reactive ion etching (RIE) processes, large numbers of ions are produced that are accelerated towards the target and physically remove material by sputtering and related processes. In contrast to RIE, inductively coupled plasma (ICP) etching is a largely chemical process in which a plasma is used to breakdown the etching gases into a mixture of free radicals (i.e. neutral species) and ions (i.e. charged species). The plasma can consist of oxygen, Ar, fluorine and other species.

FIG. 3 illustrates an integration scheme where blanket diamond is bonded to the blanket device layer. (A) Blanket MCD 11 onto a growth substrate 12; (B) Blanket device layer 20-1; (C) permanent bonding of the layers shown in (a) and (b); (D) removing a growth substrate and (E) vias opening creation 33 in both layers by any of the mentioned methods; (F) removing a temporary carrier and a temporary bonding layer.

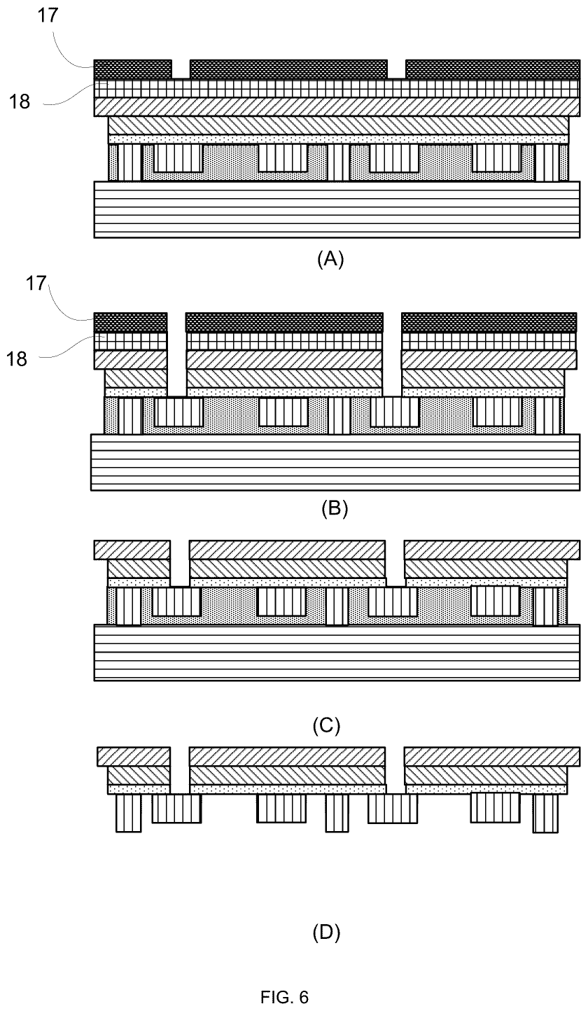

FIG. 6 shows schematic representation of the sequence. A photoresist with openings 17 is formed on top of hard mask 18. The hard mask is used in this process because of the chemical similarity of MCD and PR reaction with oxidizing species. The added value of such a sequence is an ability switch this process between MCD and device layer changing the gas chemistry or other process conditions.

The sequence may include (A) MCD substrate covered by hard mask 18 and photoresist 17, (B) Vias opening in hard mask, and via holes dry etching in MCD, (C) removal of photoresist and hard mask and (D) removing a temporary carrier and a temporary bonding layer.

FIG. 8 illustrates the filling of via holes to provide vias 65. The filling may be preceded by any of the methods of FIGS. 1-3 and 6.

FIG. 9 illustrates a method in which (A) via holes are formed in the initial MCD stack and are filled to provide vias-before the bonding, (B) via holes are formed in the device layer and are filled to provide vias-before the bonding, (C) bonding, (D) removing the growth substrate and (E) removing the temporary carrier.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

Any reference to any of the terms “comprise”, “comprises”, “comprising” “including”, “may include” and “includes” may be applied to any of the terms “consists”, “consisting”, “consisting essentially of”.

Any reference to the phrase “may be” should also be interpreted as “may not be”.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “rear” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between various components are merely illustrative and that alternative embodiments may merge various components or impose an alternate decomposition of functionality upon various components. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” Each other such that the desired functionality is achieved, irrespective of architectures or intermedial components. Likewise, any two components so associated can also be viewed as being “operably connected,” or “operably coupled,” to Each other to achieve the desired functionality.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

We claim:

1. A method for manufacturing a diamond cooled device, the method comprises:
obtaining a semiconductor item that comprises active elements that emit heat during operation;
obtaining via location information regarding vias associated with the active elements;
obtaining a diamond layer that comprises openings that are located at positions determined based on the via location information; and
bonding the diamond layer to the semiconductor item to provide a bonded item, following the obtaining of the diamond layer.

2. The method according to claim 1, comprising forming, following the bonding, semiconductor via holes using the diamond layer as a mask.

3. The method according to claim 1, comprising forming, following the bonding, semiconductor via holes using a mask that differs from the diamond layer.

4. The method according to claim 1, wherein the obtaining of the diamond layer comprises forming the openings as an integral part of a growth of the diamond layer.

5. The method according to claim 1, wherein the obtaining of the diamond layer comprises growing the diamond layer over a patterned growth structure configured to introduce the openings.

6. The method according to claim 5, wherein the patterned growth structure was designed by a design process that was based on design information regarding the semiconductor item.

7. The method according to claim 1, wherein the positions of the openings are determined based on estimated locations of hotspots formed by the emission of the heat from the active elements during operation.

8. The method according to claim 7, wherein the positions of the openings are also determined based on locations of vias to be formed in the semiconductor item.

9. The method according to claim 1, wherein the obtaining of the via location information regarding vias associated with the active elements comprises determining the via locations based on design information regarding the semiconductor item.

10. The method according to claim 9, wherein the determining of the via locations is also based on estimated locations of hotspots formed by the emission of the heat from the active elements during operation.

11. The method according to claim 1, wherein the obtaining of the diamond layer comprises obtaining the diamond layer in which the openings are filled.

12. The method according to claim 1 wherein the obtaining of the diamond layer comprises obtaining the diamond layer in which the openings are filled with electric conductive material.

13. The method according to claim 1 wherein the obtaining of the diamond layer comprises obtaining the diamond layer in which the openings are unfilled.

14. A method for manufacturing a diamond interposer, the method comprises:
obtaining a semiconductor item that comprises active elements that emit heat during operation;
obtaining via location information regarding vias associated with the active elements;
obtaining a diamond layer that comprises openings that are located at positions determined based on the via location information; and
bonding the diamond layer to the semiconductor item to provide a bonded item, following the obtaining of the diamond layer.

15. The method according to claim 14, wherein the obtaining of the diamond layer comprises obtaining the diamond layer in which the openings are filled.

16. The method according to claim 14, wherein the obtaining of the diamond layer comprises obtaining the diamond layer in which the openings are filled with electric conductive material.

17. The method according to claim 14, wherein the obtaining of the diamond layer comprises obtaining the diamond layer in which the openings are unfilled.
